(19) United States
(12) Patent Application Publication
(10) Pub. No.: US 2025/0079161 A1
(43) Pub. Date: Mar. 6, 2025

(54) DEPOSITION OF ORGANIC MATERIAL

(71) Applicant: ASM IP Holding B.V., Almere (NL)

(72) Inventors: Adam Vianna, Phoenix, AZ (US); Krzysztof Kamil Kachel, Chandler, AZ (US); Anirudhan Chandrasekaran, Scottsdale, AZ (US); Yi Cheng Zhang, Scottsdale, AZ (US)

(21) Appl. No.: 18/816,095

(22) Filed: Aug. 27, 2024

Related U.S. Application Data
(60) Provisional application No. 63/535,556, filed on Aug. 30, 2023.

(51) Int. Cl. H01L 21/02; C23C 16/02; C23C 16/04; C23C 16/455

(52) U.S. Cl. CPC H01L 21/0228; C23C 16/0227; C23C 16/04; C23C 16/45544; C23C 16/45553; H01L 21/02118; H01L 21/02205; H01L 21/02301

(57) ABSTRACT

In one aspect, a method, system and apparatus are disclosed for selectively depositing a layer of organic material on a substrate including a first surface and a second surface by a cyclic deposition process, the process includes providing a substrate in a reaction chamber, providing a first vapor-phase precursor in the reaction chamber, and providing a second vapor-phase precursor in the reaction chamber, where the first and second vapor-phase precursors form the organic material selectively on the first surface relative to the second surface, and where the first vapor-phase precursor includes a diamine or triamine compound.

### CROSS-REFERENCE TO RELATED APPLICATIONS

This application is a nonprovisional of, and claims priority to and the benefit of, U.S. Provisional Patent Application No. 63/535,556, filed Aug. 30, 2023 and entitled “DEPOSITION OF ORGANIC MATERIAL,” which is hereby incorporated by reference herein.

### FIELD

The present disclosure relates to methods and apparatuses for the manufacture of semiconductor devices. More particularly, the disclosure relates to methods and apparatuses for depositing an organic layer selectively on a substrate comprising at least two different surfaces.

### BACKGROUND

Semiconductor device fabrication processes generally use advanced deposition methods. Patterning is conventionally used in depositing different materials on semiconductor substrates. Selective deposition, which is receiving increasing interest among semiconductor manufacturers, could enable a decrease in steps needed for conventional patterning, reducing the cost of processing. Selective deposition could also allow enhanced scaling in narrow structures. Various alternatives for bringing about selective deposition have been proposed, and additional improvements are needed to expand the use of selective deposition in industrial-scale device manufacturing.

Organic polymer layers can be used, for example, as a starting point in semiconductor applications for amorphous carbon films or layers. As an example, polyimide-containing layers are valuable for their thermal stability and resistance to mechanical stress and chemicals, and they have been described as passivation layers to allow selective deposition of different materials.

Vapor-phase deposition processes such as chemical vapor deposition (CVD), vapor deposition polymerization (VDP), molecular layer deposition (MLD), and sequential deposition processes such as atomic layer deposition (ALD) and cyclical CVD may be used to deposit organic polymer layers. In such processes, the precursors used to deposit the material have an important role in the properties of the deposited layers. This, again, affects the material's usability when different materials are selectively deposited on different surface combinations. Thus, a need exists in the art to broaden the selection of precursors for the deposition of organic polymer layers.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

In one aspect, a method for selectively depositing a layer of organic material on a substrate including a first surface and a second surface by a cyclic deposition process, the process includes providing a substrate in a reaction chamber, providing a first vapor-phase precursor in the reaction chamber, and providing a second vapor-phase precursor in the reaction chamber, where the first and second vapor-phase precursors form the organic material selectively on the first surface relative to the second surface, and where the first vapor-phase precursor includes a triamine compound having three amine groups and at least three carbon atoms, where the amine groups are primary amines. The method may also include where the second vapor-phase precursor includes a dianhydride. The method may also include where the organic material includes a polyimide and/or a polyamic acid. The method may also include where the second surface includes an inorganic dielectric surface and/or silicon. The method may also include where the organic material is deposited on the first surface relative to the second surface with a selectivity of above about 50%.

The method may also include where the first surface includes a metal oxide, metal nitride, elemental metal, or metallic surface.

The method may also include where the first surface includes a metal selected from a group consisting of aluminum, copper, tungsten, cobalt, nickel, niobium, iron, molybdenum, indium, gallium, manganese, zinc, ruthenium and vanadium.

The method may also include where the triamine compound is a C3 to C11 compound.

The method may also include where the triamine is a triaminopropane, triamino butane, triamino pentane, triamino hexane, triamino heptane, or triamino octanes, or a combination thereof.

The method may also include where the triamine compound is: tris(aminoethyl)phosphane; tris(aminoethyl)arsane; bis(aminoethyl)aminomethylamine; tris(aminoethyl)silane; tris(aminoethyl)stannane; tris(aminoethyl)methylsilane; 2-methylbenzene-1,3,5-triamine; pentane-1,2,4-triamine; cyclohexane-1,3,5-triamine; pentane-1,3,5-triamine; tris(2-aminoethyl)amine; 2-aminomethyl-1,3-diaminopropane; 2-(aminomethyl)propane-1,3-diamine; propane-1,2,3-triamine; 2-aminomethyl-1,4-diaminobutane; tris(2-aminoethyl)phosphane; 2-aminomethyl-1,5-diaminopentane; 3-aminomethyl-1,5-diaminopentane; 2-aminomethyl-1,6-diaminohexane; 3-aminomethyl-1,6-diaminohexane; 3-aminoethyl-1,6-diaminohexane, 2-methylbenzene-1,3,5-triamine, 1,3,5-triaminobenzene, or combinations thereof.

The method may also include where the method includes a preclean includes a reduction and an oxidation step before depositing the organic material on the first surface of the substrate. Other technical features may be readily apparent to one skilled in the art from the following figures, descriptions, and claims.

In one aspect, a method for selectively depositing a layer of organic material on a substrate including a first surface and a second surface by a cyclic deposition process, the process includes contacting the substrate with a first vapor-phase precursor, and contacting the substrate with a second vapor-phase precursor, where the first and second vapor-phase precursors form the organic material selectively on the first surface relative to the second surface; and where the first vapor-phase precursor includes a triamine compound includes at least three carbon atoms where the amine groups are primary amines.

In one aspect, a method for selectively depositing a layer of organic material on a substrate including a first surface and a second surface by a cyclic deposition process, the process includes providing a substrate in a reaction chamber, providing a first vapor-phase precursor in the reaction chamber, and providing a second vapor-phase precursor in the reaction chamber, where the first and second vapor-phase precursors form the organic material selectively on the first surface relative to the second surface, and where the first vapor-phase precursor includes a diamine compound having both amine groups bonded to a cyclic carbon backbone, or a backbone with one or more carbon-carbon double bonds or carbon-carbon triple bonds, or a combination thereof.

The method may also include where the diamine includes trans-1,4-diaminocyclohexane, 2,4-diamino-2,4-dimethylpentane, 1,5-diamino-2-methylpentane, 1,3-diamino-3-methylbutane, 2,5-diamino-2,5-dimethylhexane, 1,2-diaminocyclopropane, 1,3-diaminocyclobutane, 1,3-diaminocyclohexane, 1,3-diaminocyclopentane, 1,4-diaminocyclohexane; 1,3-diaminocycloheptane, 1,4-diaminocycloheptane, 2,7-diamino-2,7-dimethyloctane, diaminocyclohexane, 1,3-diaminobenzene and 1,4-diaminobenzene, or cis or trans stereoisomers thereof. Other technical features may be readily apparent to one skilled in the art from the following figures, descriptions, and claims.

In one aspect, a method of selectively depositing an inorganic material on a second surface of a substrate relative to a first surface of the substrate by a cyclic deposition process, where the process includes depositing a layer of organic material on the first surface by providing a substrate in a reaction chamber, providing a first vapor-phase precursor in the reaction chamber, and providing a second vapor-phase precursor in the reaction chamber, where the first and second vapor-phase precursors form the organic material selectively on the first surface relative to the second surface, and where the first vapor-phase precursor includes a triamine compound having three primary amines and at least three carbon atoms, and depositing the inorganic material on the second surface.

In one aspect, a deposition assembly for selectively depositing a layer of organic material on a substrate includes one or more reaction chambers constructed and arranged to hold the substrate, a precursor injector system constructed and arranged to provide a first precursor and a second precursor into the reaction chamber in a vapor phase, where the deposition assembly includes a precursor vessel constructed and arranged to contain a first precursor, and where the assembly is constructed and arranged to provide the first precursor including a triamine and the second precursor including a dianhydride via the precursor injector system to the reaction chamber to deposit a layer of organic material on the substrate, and where the triamine compound includes at least three carbon atoms and where the amine groups are primary amines.

The method may also include where the second surface includes SiO2.

The method may also include where the triamine compound includes a cis- or trans stereoisomer, or combination thereof. Other technical features may be readily apparent to one skilled in the art from the following figures, descriptions, and claims.

As used herein, the term “substrate” may refer to any underlying material or materials that may be used to form, or upon which, a device, a circuit, material or a material layer may be formed. A substrate can include a bulk material, such as silicon (such as single-crystal silicon), other Group IV materials, such as germanium, or other semiconductor materials, such as a Group II-VI or Group III-V semiconductor materials. A substrate can include one or more layers overlying the bulk material. The substrate can include various topologies, such as gaps, including recesses, lines, trenches or spaces between elevated portions, such as fins, and the like formed within or on at least a portion of a layer of the substrate. Substrate may include nitrides, for example TiN, oxides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials. In some examples of the current disclosure, the substrate comprises silicon. The substrate may comprise other materials, as described above, in addition to silicon. The other materials may form layers. A substate according to the current disclosure comprises two surfaces having different material properties.

As used herein, the term “layer” and/or “film” can refer to any continuous or non-continuous structure and material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. A seed layer may be a non-continuous layer serving to increase the rate of nucleation of another material. However, the seed layer may also be substantially or completely continuous.

In this disclosure, “gas” can include material that is a gas at normal temperature and pressure (NTP), a vaporized solid and/or a vaporized liquid, and can be constituted by a single gas or a mixture of gases, depending on the context. Precursors according to the current disclosure may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

The terms “precursor” and “reactant” can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may me an element or a compound that is not incorporated into the resulting compound or element to a significant extent. However, a reactant may also contribute to the resulting compound or element in certain examples.

In some examples, a precursor is provided in a mixture of two or more compounds. In a mixture, the other compounds in addition to the precursor may be inert compounds or elements. In some examples, a precursor is provided in a composition. Compositions suitable for use as composition can include Composition may be a solution or a gas in standard conditions.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some examples. In this disclosure, any defined meanings do not necessarily exclude ordinary and customary meanings in some examples.

### BRIEF DESCRIPTION OF DRAWINGS

The accompanying drawings, which are included to provide a further understanding of the disclosure and constitute a part of this specification, illustrate exemplary examples, and together with the description help to explain the principles of the disclosure. In the drawings

FIG. 1 illustrates selective deposition according to the current disclosure.

FIGS. 2A and 2B illustrate a block diagram of a process according to the current disclosure.

FIG. 3 is a schematic presentation of depositing an organic layer according to the current disclosure on a metal surface relative to a dielectric surface of a substrate.

FIG. 4 is a schematic presentation of a vapor deposition assembly according to the current disclosure.

### DETAILED DESCRIPTION

The detailed description of various examples herein makes reference to the accompanying drawings, which show the exemplary examples by way of illustration. While these exemplary examples are described in sufficient detail to enable those skilled in the art to practice the disclosure, it should be understood that other examples may be realized and that logical, chemical, and/or mechanical changes may be made without departing from the spirit and scope of the disclosure. Thus, the detailed description herein is presented for purposes of illustration only and not of limitation. For example, the steps recited in any of the method or process descriptions can be executed in any combination and/or order and are not limited to the combination and/or order presented. Further, one or more steps from one of the disclosed methods or processes can be combined with one or more steps from another of the disclosed methods or processes in any suitable combination and/or order. Moreover, any of the functions or steps can be outsourced to or performed by one or more third parties. Furthermore, any reference to singular includes plural examples, and any reference to more than one component can include a singular example.

Although certain examples and examples are disclosed below, it will be understood by those in the art that the disclosure extends beyond the specifically disclosed examples and/or uses of the disclosure and obvious modifications and equivalents thereof. Thus, it is intended that the scope of the disclosure should not be limited by the particular examples described herein.

The illustrations presented herein are not meant to be actual views of any particular material, apparatus, structure, or device, but are merely representations that are used to describe examples of the disclosure.

As used herein, the term “substrate” can refer to any underlying material or materials that may be used, or upon which, a device, a circuit, or a film/layer may be formed.

As used herein, the term “atomic layer deposition” (ALD) can refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) can subsequently be introduced into the process chamber for use in converting the chemisorbed precursor to the desired material on the deposition surface. Typically, this reactant is capable of further reaction with the precursor. Further, purging steps can also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) can refer to any process wherein a substrate is exposed to one or more volatile precursors, which react and/or decompose on a substrate surface to produce a desired deposition.

As used herein, the terms “layer,” “film,” and/or “thin film” can refer to any continuous or non-continuous structures and material deposited by the methods disclosed herein. For example, “layer,” “film,” and/or “thin film” could include 2D materials, nanorods, nanotubes, or nanoparticles or even partial or full molecular layers or partial or full atomic layers or clusters of atoms and/or molecules. “Layer,” “film,” and/or “thin film” can comprise material or a layer with pinholes, but still be at least partially continuous. Further, in this disclosure, any two numbers of a variable can constitute a workable range of the variable, and any ranges indicated can include or exclude the endpoints. Additionally, any values of variables indicated (regardless of whether they are indicated with “about” or not) can refer to precise values or approximate values and include equivalents, and can refer to average, median, representative, majority, or the like. Further, in this disclosure, the terms “including,” “constituted by” and “having” can refer independently to “typically or broadly comprising,” “comprising,” “consisting essentially of,” or “consisting of” in some examples. In this disclosure, any defined meanings do not necessarily exclude ordinary and customary meanings in some examples.

### Surfaces

According to some aspects of the present disclosure, selective deposition can be used to deposit an organic material on a first surface relative to a second surface. The two surfaces can have different material properties. In some examples, an organic material is selectively deposited on a first conductive (e.g., metal or metallic) surface of a substrate relative to a second dielectric surface of the substrate. In some examples, the second surface comprises hydroxyl (—OH) groups, such as a silicon oxide-based surface. In some examples, the second surface may additionally comprise hydrogen (—H) terminations, such as an HF dipped Si or HF dipped Ge surface. In such examples, the surface of interest will be considered to comprise both the —H terminations and the material beneath the —H terminations. In some examples, an organic material such as a polyamic acid or polyimide is selectively deposited on a first dielectric surface of a substrate relative to a second, different dielectric surface. In some such examples, the dielectrics have different compositions (e.g., silicon, silicon nitride, carbon, silicon oxide, silicon oxynitride, germanium oxide). In other such examples, the dielectrics can have the same basic composition (e.g., silicon oxide-based layers) but different material properties due to the manner of formation (e.g., thermal oxides, native oxides, deposited oxides). In some examples, vapor deposition methods are used. In some examples, cyclical vapor deposition is used, for example, cyclical CVD or atomic layer deposition (ALD) processes are used. After selective deposition of the organic material is completed, further processing can be carried out to form the desired structures. Advantageously, selectivity can be achieved without blocking agents on the surface to receive less of the organic layer; and/or without catalytic agents on the surface to receive more of the organic layer. However, in some examples, blocking agents that prevent or reduce the deposition of the organic layer on the second surface are used.

For examples in which one surface of the substrate comprises a metal, the surface is referred to as a metal surface. It may be a metal surface or a metallic surface. In some examples the metal or metallic surface may comprise metal, metal oxides, and/or mixtures thereof. In some examples the metal or metallic surface may comprise surface oxidation. In some examples the metal or metallic material of the metal or metallic surface is electrically conductive with or without surface oxidation. In some examples, metal or a metallic surface comprises one or more transition metals. In some examples, the metal or metallic surface comprises one or more transition metals from row 4 of the periodic table of elements. In some examples, the metal or metallic surface comprises one or more transition metals from groups 4 to 11 of the periodic table of elements. In some examples, a metal or metallic surface comprises aluminum (Al). In some examples, a metal or metallic surface comprises one or more of copper (Cu), tungsten (W), cobalt (Co), nickel (Ni), niobium (Nb), iron (Fe), molybdenum (Mo), one or more noble metals, a conductive metal oxide, a conductive metal nitride, a conductive metal carbide, a conductive metal boride, or the like, or a combination thereof. In some examples, the metal or metallic surface comprises a combination of conductive materials. For example, the metal or metallic surface may comprise one or more of RuOx, NbCx, NbBx, NiOx, CoOx, NbOx, WNCx, TaN, or TiN.

In some examples, a metal or metallic surface comprises a metal selected from a group consisting of Al, Mn, Fe, Co, Ni, Cu, Zn, Nb, Mo, Ru and W. In some examples, the metal or metallic surface comprises a transition metal selected from a group consisting of Zn, Fe, Mn and Mo. In some examples, a metallic surface comprises titanium nitride.

In some examples the metal or metallic surface may be any surface that can accept or coordinate with the first or second precursor utilized in a selective deposition process as described herein.

In some examples, an organic material is selectively deposited on a metal oxide surface relative to another surface. A metal oxide surface may contain, for example a CoOx, MoOx, RuOx, WOx, HfOx, TiOx, AlOx GaOx, InOx or ZrOx surface. In some examples, a metal oxide surface is an oxidized surface of a metallic material. In some examples, a metal oxide surface is created by oxidizing at least the surface of a metallic material using oxygen compound, such as compounds comprising O₃, H₂O, H₂O₂, O₂, oxygen atoms, plasma or radicals or mixtures thereof. In some examples, a metal oxide surface is a native oxide formed on a metallic material.

In some examples, the first surface may comprise a passivated metal surface, for example a passivated Cu surface. That is, in some examples, the first surface may comprise a metal surface comprising a passivation layer, for example an organic passivation layer such as a benzotriazole (BTA) layer.

In some examples, an organic material is selectively deposited on a first dielectric surface relative to a second SiO₂ surface. In some examples, an organic material is selectively deposited on a first dielectric surface relative to a second Si or Ge surface, for example an HF-dipped Si or HF-dipped Ge surface.

In some examples, an organic material is selectively deposited on a first metal or metallic surface of a substrate relative to a second dielectric surface of the substrate. In some examples, the first surface comprises a metal oxide, elemental metal, or metallic surface. In some examples, the first surface comprises a metal selected from a group consisting of aluminum, copper, tungsten, cobalt, nickel, niobium, iron, molybdenum, indium, gallium, manganese, zinc, ruthenium and vanadium. In some examples, the organic material that is selectively deposited is a polyamic acid, polyimide, or other polymeric material. The term dielectric is used in the description herein for the sake of simplicity in distinguishing from the other surface, namely the metal or metallic surface. It will be understood by the skilled artisan that not all non-conducting surfaces are dielectric surfaces. For example, the metal or metallic surface may comprise an oxidized metal surface that is electrically non-conducting or has a very high resistivity. Selective deposition processes taught herein are for deposition on such non-conductive metallic surfaces with minimal deposition on adjacent dielectric surfaces.

In some examples, an organic material is selectively deposited on a first metal oxide surface of a substrate relative to a second SiO₂ surface. In some examples, the first metal oxide surface may contain, for example a CoOx, MoOx, RuOx, WOx, HfOx, TiOx, AlOx GaOx, InOx or ZrOx surface. In some examples, the second SiO₂ surface may be, for example, a native oxide, a thermal oxide or a chemical oxide. In some examples, an organic material is selectively deposited on a first metal oxide surface relative to a second Si or Ge surface, for example an HF-dipped Si or HF-dipped Ge surface.

In some examples, a substrate is provided comprising a first metal or metallic surface and a second dielectric surface. In some examples, a substrate is provided that comprises a first metal oxide surface. In some examples, the second surface may comprise OH groups. In some examples, the second surface may be a SiO₂ based surface. In some examples, the second surface may comprise Si—O bonds. In some examples, the second surface may comprise a SiO₂-based low-k material. In some examples, the second surface may comprise more than about 30%, preferably more than about 50% of SiO₂. In some examples, the second surface may comprise GeO₂. In some examples, the second surface may comprise Ge—O bonds. In some examples, an organic material is selectively deposited on a first metal or metallic surface relative to a second Si or Ge surface, for example an HF-dipped Si or HF-dipped Ge surface.

In certain examples the first surface may comprise a silicon dioxide surface and the second dielectric surface may comprise a second, different silicon dioxide surface. For example, the first surface may comprise a naturally or chemically grown silicon dioxide surface. In some examples, the second surface may comprise a thermally grown silicon dioxide surface. In other examples, the first or the second surface may be replaced with a deposited silicon oxide layer. Therefore, in some examples, organic material may be selectively deposited on a first silicon dioxide surface of a substrate relative to a second silicon dioxide surface that was formed by a different technique and therefore has different material properties.

In some examples, the substrate may be pretreated or cleaned prior to or at the beginning of the selective deposition process. In some examples, the substrate may be subjected to a plasma cleaning process prior to or at the beginning of the selective deposition process. In some examples, a plasma cleaning process may not include ion bombardment, or may include relatively small amounts of ion bombardment. For example, in some examples, the substrate surface may be exposed to plasma, radicals, excited species, and/or atomic species prior to or at the beginning of the selective deposition process. In some examples, the substrate surface may be exposed to hydrogen plasma, radicals, or atomic species prior to or at the beginning of the selective deposition process. In some examples, a pretreatment or cleaning process may be carried out in the same reaction chamber as a selective deposition process. However, in some examples, a pretreatment or cleaning process may be carried out in a separate reaction chamber.

In some examples, a blocking agent, such as silylating agent, is used to block the second surface before depositing the organic material on the first surface. In some examples, a second surface, such as an oxide surface, on a substrate is blocked by silylation with a silylating agent such as alyltrimethylsilane (TMS-A), chlorotrimethylsilane (TMS-Cl), N-(trimenthylsilyl)imidazole (TMS-Im), octadecyltrichlorosilane (ODTCS), hexamethyldisilazane (HMDS), or N-(trimethylsilyl)dimethylamine (TMSDMA) and organic material is selectively deposited on a first surface of the same substrate. The substrate may be contacted with a sufficient quantity of the blocking agent and for a sufficient period of time that the second surface is selectively blocked with silicon species.

### Deposition Processes

Selective deposition using the methods described herein can advantageously be achieved without treatment of the second dielectric surface to block deposition thereon and/or without treatment of the first surface (whether metallic or a different dielectric surface) to catalyze deposition. As a result, in some examples, the second dielectric surface does not comprise a passivation or blocking layer, such as a self-assembled monolayer (SAM), which would prevent the actual top surface of the second dielectric surface from being exposed to the chemicals of the deposition processes described herein. Thus, in some examples, selectivity is achieved despite the lack of blocking or catalyzing agents, and both first and second surfaces are directly exposed to the deposition precursors. Even in material pairs for which selectivity is not perfect, etch-back or similar corrective treatments using, for example, plasma, may allow selective deposition of organic material.

Vapor-phase deposition techniques can be applied to organic layers and polymers such as polyimide films, polyamide films, polyurea films, polyurethane films, polythiophene films, and more. CVD of polymer films can produce greater thickness control, mechanical flexibility, conformal coverage, and biocompatibility as compared to the application of liquid precursor. Sequential deposition processing of polymers can produce high growth rates in small research scale reactors. Similar to CVD, sequential deposition processes can produce greater thickness control, mechanical flexibility, and conformality.

In some examples, the cyclic deposition process according to the current disclosure comprises a thermal deposition process. In thermal deposition, the chemical reactions are promoted by increased temperature relevant to ambient temperature. Generally, temperature increase provides the energy needed for the formation of organic material in the absence of other external energy sources, such as plasma, radicals, or other forms of radiation.

In the current disclosure, the deposition process may comprise a cyclic deposition process, such as an atomic layer deposition (ALD) process, a cyclic chemical vapor deposition (VCD) process, molecular layer deposition (MLD), or hybrids thereof irrespective of the reaction mechanism. The term “cyclic deposition process” (or sequential deposition) can refer to the sequential introduction of precursor(s) and/or reactant(s) into a reaction chamber to deposit material, such as organic material, for example polyimide or polyamic acid, on a substrate. Cyclic deposition includes processing techniques such as atomic layer deposition (ALD), cyclic chemical vapor deposition (cyclic CVD), and hybrid cyclic deposition processes that include an ALD component and a cyclic CVD component. The process may comprise a purge step between providing precursors into the reaction chamber.

As used herein, the term “purge” may refer to a procedure in which vapor-phase precursors and/or vapor-phase byproducts are removed from the substrate surface for example by evacuating the reaction chamber with a vacuum pump and/or by replacing the gas inside a reaction chamber with an inert or substantially inert gas such as argon or nitrogen. Purging may be effected between two pulses of gases which react with each other. However, purging may be effected between two pulses of gases that do not react with each other. For example, a purge, or purging may be provided between pulses of two precursors. Purging may avoid or at least reduce gas-phase interactions between the two gases reacting with each other. It shall be understood that a purge can be effected either in time or in space, or both. For example, in the case of temporal purges, a purge step can be used e.g. in the temporal sequence of providing a first precursor to a reactor chamber, providing a purge gas to the reactor chamber, and providing a second precursor to the reactor chamber, wherein the substrate on which a layer is deposited does not move. For example, in the case of spatial purges, a purge step can take the following form: moving a substrate from a first location to which a first precursor is continually supplied, through a purge gas curtain, to a second location to which a second precursor is continually supplied.

Purging times may be, for example, from about 0.01 seconds to about 90 seconds (s), or from about 0.05 s to about 80 s, or from about 0.05 s to about 70 s or from about 1 s to about 60 s, or from about 0.05 s to about 50 s or from about 0.5 s to about 40 s, or from about 0.05 s to about 30 s or, or from about 0.05 s to about 20 s, or from about 0.05 s to about 10 s, or between about 1 s and about 7 s, such as 4 s, 5 s, 6 s or 8 s, or any other suitable time period (“about” in this context means plus or minus 5 seconds). Other purge times can be utilized, such as where highly conformal step coverage over extremely high aspect ratio structures or other structures with complex surface morphology is needed, or in specific reactor types, such as a batch reactor, may be used.

The process may comprise one or more cyclic phases. For example, pulsing of first precursor and second precursor may be repeated. In some examples, the process comprises or one or more acyclic phases. In some examples, the deposition process comprises the continuous flow of at least one precursor. In some examples, a precursor may be continuously provided in the reaction chamber. In such an example, the process comprises a continuous flow of a precursor or a reactant. In some examples, one or more of the precursors and/or reactants are provided in the reaction chamber continuously.

The term “atomic layer deposition” (ALD) can refer to a vapor deposition process in which deposition cycles, such as a plurality of consecutive deposition cycles, are conducted in a reaction chamber. The term atomic layer deposition, as used herein, is also meant to include processes designated by related terms, such as chemical vapor atomic layer deposition, when performed with alternating pulses of precursor(s)/reactant(s), and optional purge gas(es). Generally, for ALD processes, during each cycle, a precursor is introduced to a reaction chamber and is chemisorbed to a deposition surface (e.g., a substrate surface that may include a previously deposited material from a previous ALD cycle or other material), forming about a monolayer or sub-monolayer of material that does not readily react with additional precursor (i.e., a self-limiting reaction). Thereafter, in some cases, another precursor or a reactant may subsequently be introduced into the process chamber for use in converting the chemisorbed precursor to the desired material on the deposition surface. The second precursor or a reactant can be capable of further reaction with the precursor. Purging steps may be utilized during one or more cycles, e.g., during each step of each cycle, to remove any excess precursor from the process chamber and/or remove any excess precursor and/or reaction byproducts from the reaction chamber. Thus, in some examples, the cyclic deposition process comprises purging the reaction chamber after providing a first precursor into the reaction chamber. In some examples, the cyclic deposition process comprises purging the reaction chamber after providing a second precursor into the reaction chamber.

CVD type processes typically involve gas phase reactions between two or more precursors and/or reactants. The precursor(s) and reactant(s) can be provided simultaneously to the reaction space or substrate, or in partially or completely separated pulses. The substrate and/or reaction space can be heated to promote the reaction between the gaseous precursor and/or reactants. In some examples the precursor(s) and reactant(s) are provided until a layer having a desired thickness is deposited. In some examples, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap. In some examples, the first precursor is supplied in pulses, the second precursor supplied in pulses and the reaction chamber is purged between consecutive pulses of first precursor and second precursor.

In some examples, the processes described herein may be batch processes, that is, the processes may be carried out on two or more substrates at the same time. In some examples, the processes described herein may be carried out on two or more, five or more, 10 or more, 25 or more, 50 or more, or 100 or more substrates at the same time. In some examples, the substrate may comprise wafers, for example, semiconductor or silicon wafers. In some examples, the substrates may have diameters of 100 mm or more, 200 mm or more, or 300 mm or more. In some instances, substrates having diameters of 450 mm or more may be desirable.

### Selectivity

Selectivity can be given as a percentage calculated by [(deposition on first surface)-(deposition on second surface)]/(deposition on the first surface). Deposition can be measured in any of a variety of ways. In some examples, deposition may be given as the measured thickness of the deposited material. In some examples, deposition may be given as the measured amount of material deposited.

In some examples, selectivity is greater than about 30%, greater than about 50%, greater than about 75%, greater than about 85%, greater than about 90%, greater than about 93%, greater than about 95%, greater than about 98%, greater than about 99% or even greater than about 99.5%. In some examples, the organic material is deposited on the first surface relative to the second surface with a selectivity of above about 50%. In examples described herein, the selectivity can change over the duration or thickness of a deposition. In some examples, selectivity increases with the duration of the deposition for the vapor-phase polymer depositions described herein. In contrast, typical selective deposition based on differential nucleation on different surfaces tends to become less selective with greater duration or thickness of a deposition.

In some examples, deposition occurs substantially only on the first surface and does not occur on the second surface. In some examples, deposition on the first surface of the substrate relative to the second surface of the substrate is at least about 80% selective, which may be selective enough for some particular applications. In some examples, the deposition on the first surface of the substrate relative to the second surface of the substrate is at least about 50% selective, which may be selective enough for some particular applications. In some examples, the deposition on the first surface of the substrate relative to the second surface of the substrate is at least about 10% selective, which may be selective enough for some particular applications.

In some examples, the organic film deposited on the first surface of the substrate may have a thickness less than about 50 nm, less than about 20 nm, less than about 10 nm, less than about 5 nm, less than about 3 nm, less than about 2 nm, or less than about 1 nm. In some examples, a ratio of material deposited on the first surface of the substrate relative to the second surface of the substrate may be greater than or equal to about 2:1, greater than or equal to about 20:1, greater than or equal to about 15:1, greater than or equal to about 10:1, greater than or equal to about 5:1, or greater than or equal to about 3:1.

In some examples, the selectivity of the selective deposition processes described herein may depend on the materials which comprise the first and/or second surface of the substrate. For example, in some examples, where the first surface comprises a Cu surface and the second surface comprises a low k material, the selectivity may be greater than about 8:1 or greater than about 15:1. In some examples, where the first surface comprises a metal or metal oxide and the second surface comprises a natural or chemical silicon dioxide surface the selectivity may be greater than about 5:1 or greater than about 10:1. In some examples, where the first surface comprises a chemical or natural silicon dioxide surface and the second surface comprises a thermal silicon dioxide surface the selectivity may be greater than about 5:1 or greater than about 10:1. In some examples, where the first surface comprises natural or chemical silicon dioxide, and the second surface comprises Si—H terminations, for example an HF dipped Si surface, the selectivity may be greater than about 5:1 or greater than about 10:1. In some examples, where the first surface comprises Si—H terminations, for example an HF dipped Si surface, and the second surface comprises thermal silicon dioxide, the selectivity may be greater than about 5:1 or greater than about 10:1.

### Selective Deposition

In some examples, a substrate comprising a first surface and a second surface is provided. The first and second surfaces may have different material properties. In some examples, the first surface may be a metallic surface and the second surface may be a dielectric surface. In some examples, a first organic precursor is vaporized to form a first precursor vapor. The precursor being vaporized may be liquid or solid under standard temperature and pressure conditions (room temperature and atmospheric pressure). In some examples, the first precursor is a liquid precursor under standard conditions. In some examples, the precursor being vaporized comprises a diamine compound or a triamine compound (e.g., 1,3-diaminopentane (1,3-DAP) or cyclohexane-1,3,5-triamine). The substrate is then exposed to the first precursor vapor. The substrate is also exposed to a second vapor-phase precursor, for example an organic precursor, such as a dianhydride. A dianhydride may be, for example, pyromellitic dianhydride (PMDA). The cyclic exposure of the substrate to the two precursors leads to the deposition of an organic material. The method can include additional steps, and may be repeated, but need not be performed in the illustrated sequence nor the same sequence in each repetition, and can be readily extended to more complex vapor deposition techniques.

In an example, the diamine according to the current disclosure may comprise at least three carbon atoms. However, in some examples, a diamine according to the current comprises four carbons. For example, a diamine according to the current disclosure may be selected from 1,2-diaminobutane, 1,3-diaminobutane and 2,4-diaminobutane. Thus, in the four-carbon examples, at least one of the amino groups is attached to a carbon atom that is bonded to two other carbon atoms. In other words, at least one of the amino groups is not located at the end of a carbon chain.

In some examples, both amine groups of the diamine may be bonded to a cyclic carbon backbone, or a carbon backbone including carbon-carbon double bonds and/or carbon-carbon triple bonds. In this context, the term “carbon backbone” means the presence of carbon atoms in a main continuous chain or ring-like structure comprising three or more carbon atoms. Such diamines may comprise, for example, one or more of: trans-1,4-diaminocyclohexane; 2,4-diamino-2,4-dimethylpentane, 1,5-diamino-2-methylpentane, 1,3-diamino-3-methylbutane, 2,5-diamino-2,5-dimethylhexane, 1,2-diaminocyclopropane, 1,3-diaminocyclobutane, 1,3-diaminocyclohexane, 1,3-diaminocyclopentane, 1,4-diaminocyclohexane; 1,3-diaminocycloheptane, 1,4-diaminocycloheptane, 2,7-diamino-2,7-dimethyloctane, diaminocyclohexane, 1,3-diaminobenzene and 1,4-diaminobenzene, or cis- or trans- stereoisomers thereof.

In some examples, the carbon chain is branched. Thus, there is at least one carbon atom which is bonded to three or four other carbon atoms. In some examples, there is one such branching position in the diamine compound. In some examples, there are two such branching positions in the diamine compound. In some examples, there are three or more branching points. In some examples, the side chain from the longer carbon chain is a methyl group. In some examples, the side chain from the longer carbon chain is an ethyl group. In some examples, the side chain from the longer carbon chain is a propyl group. In some examples, the side chain from the longer carbon chain is an isopropyl group. In some examples, the side chain from the longer carbon chain is a butyl group. In some examples, the side chain from the longer carbon chain is a tert-butyl group. In some examples, a side chain of a diamine compound is a straight alkyl chain. In some examples, a side chain of a diamine compound is a branched alkyl chain. In some examples, a side chain of a diamine compound is a cyclic alkyl chain.

In some examples, the diamine compound is a C3 to C11 compound. The number of carbon atoms in the diamine compound typically influences the volatility of the compound such that a higher-weight compound may not be as volatile as a smaller compound.

In some examples of the disclosure, the amine groups are attached to non-adjacent carbon atoms. This may have advantages for the availability for the amine groups to reactions with the second precursor. In some examples, there is one carbon atom between the amino group -binding carbon atoms. In some examples, there is at least one carbon atom between the amino group -binding carbon atoms. In some examples, there are two carbon atoms between the amino group -binding carbon atoms. In some examples, there are at least two carbon atoms between the amino group -binding carbon atoms. In some examples, there are three carbon atoms between the amino group -binding carbon atoms. In some examples, there are at least three carbon atoms between the amino group -binding carbon atoms. In some examples, there are four carbon atoms between the amino group -binding carbon atoms. In some examples, there are at least four carbon atoms between the amino group -binding carbon atoms.

In some examples, the first precursor comprises 1,5-diamino-2-methylpentane. Although the vapor pressure of 1,5-diamino-2-methylpentane is lower than that of 1,3-diaminopentane, it is also liquid at ambient temperature, and reaching vapor pressure of 1 Torr requires a moderate temperature of about 40° C.

In some examples, a carbon atom bonded with an amine nitrogen in the diamine compound is bonded to at least two carbon atoms. Thus, in some examples in which the diamine comprises three or more carbons, at least one of the amino groups is not located at the end of a carbon chain. The structure of the diamine compound affects its properties in a vapor deposition process. Branching of a diamine compound, including the number of branches, and the relative position of the amino groups to the branches, may cause the deposited organic material to have different properties. Without limiting the current disclosure to any specific theory, for example steric factors, may lead to certain reactions being preferred. This may offer the possibility to design a deposition process for a given purpose, taking into account for example the thermal budget, organic material growth speed requirements, necessary degree of selectivity, by using different diamine compounds.

In some examples, the diamine is an aromatic diamine. In some examples, the aromatic diamine is a diaminobenzene, such as 1,2-diaminobenzene, 1,3-diaminobenzene, 1,4-diaminobenzene, or cis- or trans- stereoisomers thereof. In some examples, the aromatic diamine comprises an alkylamino group in at least one position. For example, the alkylamino group may be a C1 to C3 alkylamino group, such as —CH₂NH₂, —(CH₂)₂NH₂, —(CH₂)₃NH₂, —CH(CH₃)NH₂ or —CH₂CH(CH₃)NH₂.

In some examples, the diamine is selected from a group consisting of 1,3-diaminopentane, 1,4-diaminopentane, 2,4-diaminopentane, 2,4-diamino-2,4-dimethylpentane, 1,5-diamino-2-methylpentane, 1,3-diaminobutane, 1,3-diamino-3-methylbutane, 2,5-diamino-2,5-dimethylhexane, 1,4-diamino-4-methylpentane, 1,3-diaminobutane, 1,5-diaminohexane, 1,3-diaminohexane, 2,5-diaminohexane, 1,3-diamino-5-methylhexane, 4,4,4-trifluoro-1,3-diamino-3-methylbutane, 2,4-diamino-2-methylpentane, and 4-(1-methylethyl)-1,5-diaminohexane, 3-aminobutanamide, 1,3-diamino-2-ethylhexane, 2,7-diamino-2,7-dimethyloctane, 1,4-diaminocyclohexane, diaminocyclohexane, 1,3-diaminobenzene and 1,4-diaminobenzene and trans- and cis- stereoisomers thereof. In some examples, the diamine compound comprises a halogen.

In some examples, the first precursor comprises a triamine compound (e.g., any branched aliphatic or aromatic compound containing three primary amine functional groups).

In an example, the triamine may comprise the following structure:

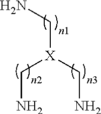

where X is C—R, Si—R, Sn—R, N, P, or As, and n1, n2, and n3 are positive integers.

Providing such molecules may advantageously affect the availability of polymerization sites for the second vapor-phase reactant. The availability of three amine groups in a single molecule, may lead to denser polymer network, which again may reduce the metal migration through the organic material. Such properties may be advantageous in examples utilizing the organic material according to the current disclosure as a passivation layer.

Examples of suitable triamines include 1,2,3-triaminopropane, triamino butane (with amines in carbons 1,2 and 3 or in carbons 1,2 and 4), triamino pentane (especially with amines in carbons 1 and 5, plus in any one of the carbons 2 or 3). Similarly, triamino hexanes may contain amine groups in carbons 1 and 6, as well as in any one of the positions 2, or 3; triamino heptanes may contain amine groups in carbons 1 and 7, as well as in any one of the positions 2, 3 or 4; and triamino octanes may contain amine groups in carbons 1 and 8, as well as in any one of the positions 2, 3 or 4. Further, branched carbon chains, notably tris(aminoethyl)phosphane; tris(aminoethyl)arsane; bis(aminoethyl)aminomethylamine; tris(aminoethyl)silane; tris(aminoethyl)stannane; tris(aminoethyl)methylsilane; 2-methylbenzene-1,3,5-triamine; pentane-1,2,4-triamine; cyclohexane-1,3,5-triamine; pentane-1,3,5-triamine; tris(2-aminoethyl)amine; 2-aminomethyl-1,3-diaminopropane; 2-(aminomethyl)propane-1,3-diamine; propane-1,2,3-triamine; 2-(aminomethyl)butane-1,4-diamine; 2-aminomethyl-1,4-diaminobutane (or alternatives having the two amino groups elsewhere in the butane chain); tris(2-aminoethyl)phosphane; 2-aminomethyl-1,5-diaminopentane (or alternatives having the two amino groups elsewhere in the pentane chain); 3-aminomethyl-1,5-diaminopentane (or alternatives having the two amino groups elsewhere in the pentane chain); 2-aminomethyl-1,6-diaminohexane (or alternatives having the two amino groups elsewhere in the hexane chain); 3-aminomethyl-1,6-diaminohexane (or alternatives having the two amino groups elsewhere in the hexane chain); 3-aminoethyl-1,6-diaminohexane (or alternatives having the two amino groups elsewhere in the hexane chain), or cis or trans stereoisomers thereof may be an alternative for certain examples. Also, an aromatic triamines, such as 2-methylbenzene-1,3,5-triamine, and/or 1,3,5-triaminobenzene or cis or trans stereoisomers thereof, may be an alternative for certain examples.

In some examples, the organic film comprises a polymer. In some examples, the polymer deposited is a polyimide. In some examples, the polymer deposited is a polyamic acid. Thus, in some examples, the organic material comprises polyimide. In some examples, the organic material consists substantially only of polyimide. In some examples, the organic material comprises polyamic acid. In some examples, the organic material consists substantially only of amide and polyimide. In some examples, the organic material is deposited at temperatures below 190° C., and subsequently heat-treated at a temperature of about 190° C. or higher (such as 200° C. or 210° C.) to increase the proportion of the organic material from polyamic acid to polyimide. Other examples of deposited polymers include dimers, trimers, polyurethanes, polythioureas, polyesters, polyimines, other polymeric forms or mixtures of the above materials.

In some examples, the second vapor-phase precursor comprises pyromellitic dianhydride (PMDA).

In some examples the substrate is thermally annealed for a period of about 1 to about 15 minutes. In some examples the substrate is thermally annealed at a temperature of about 200 to about 5000° C. In some examples the thermal anneal step comprises two or more steps in which the substrate is thermally annealed for a first period of time at a first temperature and then thermally annealed for a second period of time at a second temperature.

Additional treatments, such as heat or chemical treatment, can be conducted prior to, after or between the processing steps described herein. For example, treatments may modify the surfaces or remove portions of the material on the substrate surfaces exposed at various stages of the process. In some examples, the substrate may be pretreated or cleaned prior to or at the beginning of the selective deposition of organic material. In some examples, the substrate may be subjected to a plasma cleaning process at prior to or at the beginning of the selective deposition of organic material. In some examples, a plasma cleaning process may not include ion bombardment, or may include relatively small amounts of ion bombardment. For example, in some examples the substrate surface may be exposed to plasma, radicals, excited species, and/or atomic species prior to or at the beginning of the selective deposition of organic material. In some examples, the substrate surface may be exposed to hydrogen plasma, radicals, or atomic species prior to or at the beginning of the selective deposition of organic material. In some examples, a pretreatment or cleaning process may be carried out in the same reaction chamber as a selective deposition of organic material, however in some examples a pretreatment or cleaning process may be carried out in a separate reaction chamber.

### DRAWINGS

The disclosure is further explained by the following exemplary examples depicted in the drawings. The illustrations presented herein are not meant to be actual views of any particular material, structure, device or an apparatus, but are merely schematic representations to describe examples of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated examples of the present disclosure. The structures and devices depicted in the drawings may contain additional elements and details, which may be omitted for clarity.

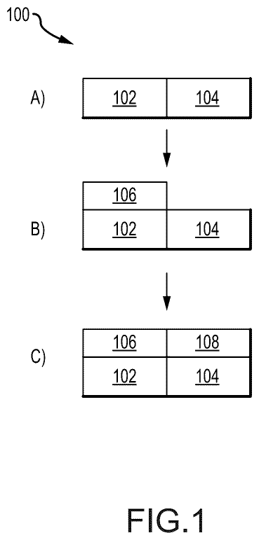

FIG. 1 is a schematic representation of selective deposition of organic material according to the current disclosure. The substrate 100 comprises a first surface 102 comprising a first material and a second surface 104 comprising a second material. In the exemplary embodiment of FIG. 1, a substrate 100 comprising a first surface 102 having a first material and a second surface 104 comprising a second material is depicted. The substrate 100 may comprise additional layers below the surface. In panel a), the surface of the substrate is formed by the first surface 102 and second surface 104. The first surface 102 comprises, consist essentially of, or consist of first material. The second surface 104 comprises, consist essentially of, or consist of second material. First material and second material are different materials. In the illustration of FIG. 1, the first surface 102 and the second surface 104 are on the same vertical level. However, in reality, the first and second surfaces 102, 104 could be on different levels.

Organic material, such as polyimide-containing material, is deposited on the first surface 102 of the substrate 100 at phase b). The deposition process for depositing a layer of organic material on the first surface 102 of the substrate 100 comprises providing a first vapor-phase precursor in the reaction chamber, and providing a second vapor-phase precursor in the reaction chamber. The first and second vapor-phase precursors form the organic material selectively on the first surface 102 relative to the second surface 104, wherein the first vapor-phase precursor comprises a diamine compound having a structural feature that prevents rotation about one or more carbon-carbon bonds (e.g., a diamine molecule having the amine groups both bonded to a cyclic carbon backbone, or a backbone with carbon-carbon double or triple bonds, or combinations thereof) and wherein the first precursor is liquid or solid at room temperature. Next, at phase c), the inorganic material 108 is deposited on the second surface 104. In some embodiments, the deposition of the inorganic material may be performed by a cyclic deposition process, such as ALD or cyclic CVD. In some embodiments, the deposited inorganic material is a metal material, metallic material, a dielectric material or a combination thereof. In some embodiments, the deposited inorganic material is aluminum oxide. In some embodiments, the deposited inorganic material is silicon-containing material. In some embodiments, the silicon-containing material is SiO2, SiOC, SiN, metal silicate-comprising material or a combination thereof. For example, the deposited inorganic material may be yttrium-doped silicon oxide. In some embodiments, the deposited inorganic material is an oxide material. In some embodiments, the deposited material may be yttrium oxide-comprising material, zirconium oxide -comprising material, hafnium oxide -comprising material or a combination thereof. In some embodiments, the deposited inorganic material forms an etch-stop layer.

In some embodiments, especially in cases in which the substrate is exposed to air for prolonged periods of time, a preclean may be performed on the substrate to prepare the metal, such as Cu, surface for the deposition of organic material according to the current disclosure. A preclean may also remove any migrated metal particles from the dielectric surface, to prevent or to reduce parasitic deposition of organic material on the dielectric surface. The preclean may comprise reduction and controlled oxidation. In some embodiments, the preclean comprises reducing the metal surface and re-oxidizing it before selective deposition. For example, an alcohol, such as ethanol, or plasma, such as H2 plasma, may be used to reduce the metal, such as Cu, surface. The strength of the treatment may be adjusted according to the degree of initial oxidation. The deeper the oxidation, the more stringent reduction treatment needs to be performed. The reduced metal surface is oxidized in a controlled way to a predetermined depth, to allow preparing the metal surface for deposition of an organic material according to the current disclosure through etching the newly formed oxide layer.

In some embodiments, the need for a preclean treatment may be avoided, if an organic layer according to the current disclosure is deposited immediately after the substrate surfaces have been prepared, typically after CMP treatment. The deposited organic material may be heated to at least 150° C., such as from about 150° C. to about 800° C., or from about 150° C. to about 700° C., or about 600° C., or be between about 150° C. and 500° C., or about 400° C., or between about 150° C. and 300° C., or about 250° C. or between about 150° C. and 250° C., or about 200° C. (“about” in this context means plus or minus 50° C.), or any sufficient temperature. This may improve its resistance towards the underlying metal, such as Cu, layer from migrating through the material. Such a solution may allow the storage of the prepared substrates, giving more flexibility to design a deposition process flow.

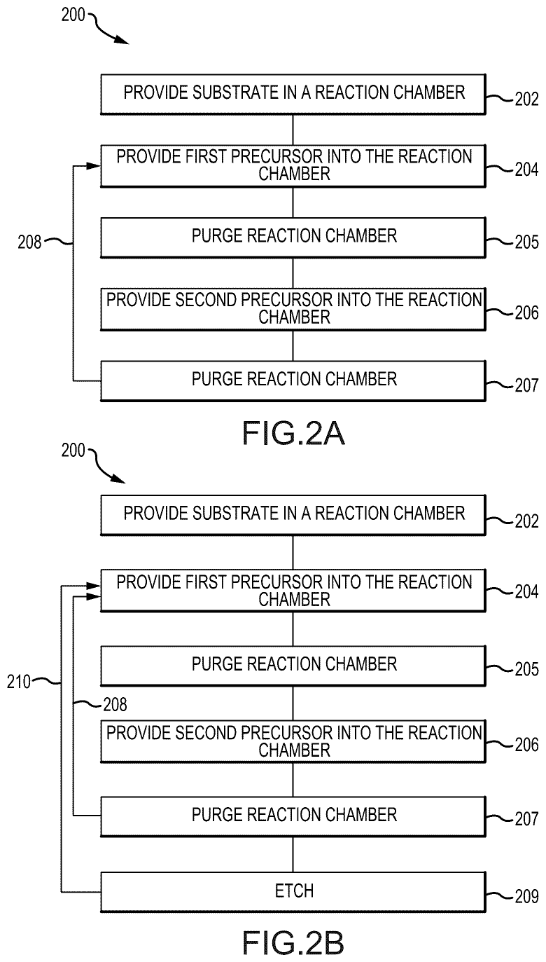

FIGS. 2A and 2B depict an aspect of the current invention in which a layer of organic material is selectively deposited on a substrate comprising a first surface and a second surface by a cyclic deposition process. Referring to FIG. 2A, the process 200 comprises providing a substrate in a reaction chamber at block 202. A substrate according to the current disclosure comprises a first surface and a second surface, and the first and second surfaces have different material properties. In some examples, the first surface may or may not be a conductive surface, for example a metal or metallic surface (such as a Cu, Co, W, Mo), and the second surface may be a dielectric surface (such as SiO₂, SiOC, SiN, HfO₂), or may be a semiconductive surface, or may or may not be conductive and claimed subject matter is not limited in this regard.

In some examples, the second surface comprises an inorganic dielectric surface. In some examples, the second surface comprises silicon. In some examples, the second surface comprises SiO₂. In some examples, the second surface comprises a silicon oxide -based material, such as a metal silicate. In some examples, the second surface is a high-k surface, such as hafnium oxide surface, a lanthanum oxide surface. In some examples, the second surface is an etch-stop layer. An etch-stop layer may comprise, for example a nitride.

In some examples, the first surface may be a dielectric surface and the second surface may be a second, different dielectric surface. In some examples, the first and second surfaces may have the same basic composition but may have different material properties due to different manners of formation (e.g., thermal oxide, deposited oxide, native oxide). In some examples, the first surface is a silicon-comprising surface, and the second surface is a silicon -comprising surface of different composition. For example, the first or the second surface may be a silicon oxide-based surface, such as silicon oxide or a metal silicate -comprising surface, while the other surface is a silicon nitride -based surface.

At block 204, a first vapor-phase precursor is provided into the reaction chamber. A first precursor according to the current disclosure may comprise a triamine compound comprising at least three carbon atoms and three primary amine functional groups. Providing a precursor into the reaction chamber leads to contacting the substrate with the precursor. Thus, in an aspect, the process comprises contacting the substrate with a first vapor-phase precursor and contacting the substrate with a second vapor-phase precursor.

In some examples, the first precursor is vaporized at a first temperature to form the first vapor-phase precursor. In some examples, the first precursor vapor is transported to the substrate through a gas line at a second temperature. In some examples, the second temperature is higher than the first temperature. In some examples, the substrate may be contacted with the first vapor-phase precursor at a third temperature. Thus, the reaction chamber temperature and/or the susceptor temperature may be different than the vaporization temperature and the gas line. In some examples, the third temperature is higher than the first temperature. In some examples, the third temperature is higher than the second temperature. In some examples, the third temperature is higher than the first temperature and the second temperature. In some examples, the third temperature is a susceptor temperature. In some examples, the third temperature is a susceptor temperature and it is between about 125° C. and 300° C., such as about 160° C., about 190° C., about 230° C. (“about” in this context means plus or minus 50° C.) or any sufficient temperature. In some examples, the substrate is held at a temperature higher than about 100° C., such as higher than about 150° C., during the deposition process for depositing organic material.

When the first precursor is provided into the reaction chamber at block 204, it will come in contact with the substrate. Without limiting the current disclosure to any specific theory, first precursor may be selectively chemisorbed on the first surface of the substrate relative to the seconds surface of the substrate. In some examples, the first vapor-phase precursor is provided into the reaction chamber at block 204 for a first exposure period (first precursor pulse time). In some examples, the first precursor pulse time is from about 0.01 seconds to about 60 seconds, about 0.05 seconds to about 30 seconds, about 0.1 seconds to about 10 seconds or about 0.2 seconds to about 5 seconds. The optimum exposure period can be determined experimentally based on the particular circumstances, such as substrate properties and the composition of the first surface and the second surface. In some examples, such as examples where batch reactors are used, exposure periods of greater than 60 seconds may be employed.

At block 205, the reaction chamber is purged of the first vapor-phase precursor and/or any reaction by-products. This phase of the process may be omitted in some examples. However, in many examples purging is used. In some examples, purging is performed by providing an inert gas, such as a carrier gas, into the reaction chamber for a period of time (purge time). In some examples, inert gas (e.g., Ar and/or N2) is used in purging. In some examples, purging times may be, for example, from about 0.01 seconds to about 90 seconds (s), or from about 0.05 s to about 80 s, or from about 0.05 s to about 70 s or from about 0.05 s to about 60 s, or from about 0.05 s to about 50 s or from about 0.5 s to about 40 s, or from about 0.05 s to about 30 s, or from about 0.05 s to about 20 s, or from about 0.05 s to about 10 s, or between about 1 s and 7 s, such as 5 s, 6 s or 7 s, or any other suitable time period (“about” in this context means plus or minus 5 seconds).

At block 206, a second vapor-phase precursor is provided into the reaction chamber. In some examples, the second precursor is also an organic reactant capable of reacting with adsorbed species of the first precursor under the deposition conditions. For example, the second precursor can be an anhydride, such as furan-2,5-dione (maleic acid anhydride), or more particularly a dianhydride, e.g., pyromellitic dianhydride (PMDA), or any other monomer with two reactive groups which will react with the first precursor. In some examples, the second vapor-phase precursor comprises a dianhydride. In some examples, the second vapor-phase precursor comprises PMDA.

In some examples, a second vapor-phase precursor is provided into the reaction chamber at block 206 for a second exposure period (second precursor pulse time). In some examples, the second precursor may be vaporized at a fourth temperature to form the second vapor-phase precursor. In some examples, the second precursor vapor is transported to the substrate through a gas line at a fifth temperature. In some examples, the fifth temperature is higher than the first temperature. In some examples, the second vapor-phase precursor is provided into the reaction chamber at a sixth temperature that is higher than the fourth temperature. In some examples, the sixth temperature is substantially the same as the third temperature.

In some examples, the first precursor is provided into the reaction chamber prior to the second precursor being provided into the reaction chamber. Thus, in some examples, a triamine comprising at least three carbon atoms and three primary amines, is provided into the reaction chamber prior to providing another precursor into the reaction chamber. However, in some examples, the second precursor, such as a dianhydride, is provided into the reaction chamber prior to providing the first precursor into the reaction chamber. Thus, in some examples, the substrate is contacted with an anhydride, such as furan-2,5-dione (maleic acid anhydride), or more particularly a dianhydride, e.g., pyromellitic dianhydride (PMDA) prior to being contacted with another precursor.

In the method, the first and second vapor-phase precursors form the organic material selectively on the first surface relative to the second surface, and the first vapor-phase precursor comprises a triamine compound. Without limiting the current disclosure to any specific theory, the selectivity may be at least partially due to the preferential chemisorption of the first precursor on the first surface.

In an aspect, the organic material according to the current disclosure forms a layer of organic material. The organic material may comprise polyimide, polyamic acid or both. The deposition methods disclosed herein may result in an advantageous organic material composition.

At block 207, the reaction chamber is purged of the second vapor-phase precursor and/or any reaction by-products. This phase of the process may be omitted in some examples. However, in many examples purging is used. In some examples, purging is performed by providing an inert gas (e.g., Ar and/or N2), such as a carrier gas, into the reaction chamber for a period of time (purge time). In some examples, purging times may be, for example, from about 0.01 seconds to about 90 seconds (s), or from about 0.05 s to about 80 s, or from about 0.05 s to about 70 s or from about 0.05 s to about 60 s, or from about 0.05 s to about 50 s or from about 0.5 s to about 40 s, or from about 0.05 s to about 30 s or, or from about 0.05 s to about 20 s, or from about 0.05 s to about 10 s, or between about 1 s and about 7 s, such as 5 s, 6 s or 7 s, or any other suitable time period (“about” in this context means plus or minus 5 seconds).

The use of purge phases 205 and 207 is independently optional. Thus, both or either one of the phases 205 and 207 may be performed, and the parameters, such as duration and composition of the purge gas, may be independently selected. In some examples, each deposition cycle comprises removing excess of the first vapor-phase precursor and reaction by-products after providing the first vapor-phase precursor into the reaction chamber. In some examples, each deposition cycle comprises removing excess of the second vapor-phase precursor and reaction by-products after providing the second vapor-phase precursor into the reaction chamber. However, it is possible that a deposition process comprises one or more cycles in which the purge phase is omitted. Thus, for simplicity, in the context of purging, each deposition cycle may mean “substantially each deposition cycle”.

The selective deposition process according to the current disclosure is a cyclic process. The thickness of the deposited organic material layer is determined, in addition to the conditions during providing the first precursor and the second precursor into the reaction chamber, by the number of deposition cycles 208 performed. In some examples, a deposition cycle comprises phases 204 and 206. In some examples, a deposition cycle comprises phases 204 and 206, as well as one or both of 205 and 207. In some examples, a deposition cycle comprises phases 204, 205, 206 and 207. In some examples, the first precursor and the second precursor are provided into the reaction chamber alternately and sequentially.

In some examples, a deposition cycle may be repeated until an organic layer of a desired thickness is selectively deposited. The selective deposition cycle can include additional acts, need not be in the same sequence nor identically performed in each repetition, and can be readily extended to more complex vapor deposition techniques. For example, a selective deposition cycle can include additional reactant supply processes, such as the supply and removal (relative to the substrate) of additional reactants in each cycle or in selected cycles. Though not shown, the process may additionally comprise treating the deposited film to form a polymer (for example, UV treatment, annealing, etc.).

In some examples, the organic material comprises a polyimide. In some examples, the organic material comprises a polyamic acid.

FIG. 2B depicts an example in which the method further comprises subjecting the substrate to an etch process 209 subsequent to multiple consecutive deposition cycles. The process is performed as in the example of FIG. 2A, including repeating the deposition cycle according to block 208. The etch process may be performed once at the end of the deposition process, or it can be performed intermittently after a predetermined number of deposition cycles, as depicted by block 210. After an etching process, the selective deposition of organic material may be continued.

In some examples, the etch process removes substantially all of any deposited organic material from the second surface of the substrate and does not remove substantially all of the deposited organic material from the first surface of the substrate. In some examples, the etch process comprises exposing the substrate to hydrogen atoms, hydrogen radicals, hydrogen plasma, or combinations thereof. In some examples, the etch process comprises exposing the substrate to oxygen atoms, oxygen radicals, oxygen plasma, or combinations thereof.

In some examples, the substrate may be subjected to an etch process to remove at least a portion of the deposited organic film. In some examples, an etch process subsequent to selective deposition of the organic film may remove deposited organic material from both the first surface and the second surface of the substrate. In some examples, the etch process may be isotropic.

In some examples, the etch process may remove the same amount, or thickness, of organic material from the first and second surfaces. That is, in some examples, the etch rate of the organic material deposited on the first surface may be substantially similar to the etch rate of the organic material deposited on the second surface. Due to the selective nature of the deposition processes described herein, the amount of organic material deposited on the second surface of the substrate may be substantially less than the amount of material deposited on the first surface of the substrate. Therefore, an etch process may completely remove deposited organic material from the second surface of the substrate while deposited organic material may remain on the first surface of the substrate.

In some examples, the etch process may comprise an etch process known in the art, for example a dry etch process such as a plasma etch process. In some examples, the etch process may comprise exposing the substrate to hydrogen atoms, hydrogen radicals, hydrogen plasma, or combinations thereof. For example, the etch process may comprise exposing the substrate to a plasma generated from H₂ using a power from about 10 W to about 5000 W, from about 25 W to about 2500 W, from about 50 W to about 500 W, or preferably from about 100 W to about 400 W.

In some examples, the triamine compounds according to the current disclosure may be used to deposit organic material that is more resistant to an etch process, for example to an etch process performed by hydrogen plasma as an etchant. This may be advantageous, as it may allow for easier tuning of an etching process, which again may enable a broader selectivity window.

In some examples, the etch process may comprise exposing the substrate to a plasma. In some examples, the plasma may comprise oxygen atoms, oxygen radicals, oxygen plasma, or combinations thereof. In some examples, the plasma may comprise hydrogen atoms, hydrogen radicals, hydrogen plasma, or combinations thereof. In some examples, the plasma may also comprise noble gas species, for example Ar or He species. In some examples, the plasma may consist essentially of noble gas species. In some examples, the plasma may comprise other species, for example nitrogen atoms, nitrogen radicals, nitrogen plasma, or combinations thereof. In some examples, the etch process may comprise exposing the substrate to an etchant comprising oxygen, for example O₃. In some examples, the substrate may be exposed to an etchant at a temperature of between about 30° C. and about 500° C., for example between about 100° C. and about 400° C. In some examples, the etchant may be supplied in one continuous pulse or may be supplied in multiple shorter pulses. A purge phase may be performed between etching pulses.

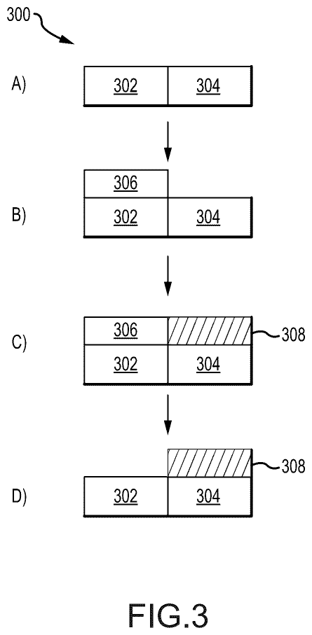

FIG. 3 depicts an aspect of the current disclosure in which inorganic material is selectively deposited on a second surface 304 of a substrate 300 relative to first a surface 302 of the substrate 300. At phase a) the substrate 300 is provided. The substrate may be provided in a reaction chamber. Organic material, such as polyimide-containing material, is deposited on the first surface 302 of the substrate 300 at phase b). The deposition process for depositing a layer of organic material on the first surface 302 of the substrate 300 comprises providing a first vapor-phase precursor in the reaction chamber and providing a second vapor-phase precursor in the reaction chamber. The first and second vapor-phase precursors form the organic material selectively on the first surface 302 relative to the second surface 304, wherein the first vapor-phase precursor comprises a triamine compound comprising at least three carbon atoms and wherein the amine groups are primary amines. Next, at phase c), the inorganic material is deposited on the second surface 304. In some examples, the deposition of the inorganic material may be performed by a cyclic deposition process, such as ALD or cyclic CVD. In some examples, the deposited inorganic material is a metal material, metallic material, a dielectric material or a combination thereof. In some examples, the deposited inorganic material is aluminum oxide. In some examples, the deposited inorganic material is silicon-containing material. In some examples, the silicon-containing material is SiO₂, SiOC, SiN, metal silicate-comprising material or a combination thereof. For example, the deposited inorganic material may be yttrium-doped silicon oxide. In some examples, the deposited inorganic material is an oxide material. In some examples, the deposited material may be yttrium oxide -comprising material, zirconium oxide -comprising material, hafnium oxide -comprising material or a combination thereof. In some examples, the deposited inorganic material forms an etch-stop layer.

At phase d) of FIG. 3, the organic material deposited on the first surface 302 is removed, leaving the deposited inorganic material on the second surface 304 and the original material of the first surface 302 as the topmost surfaces of the substrate. The above-mentioned phases can be followed by additional processing steps known in the art.

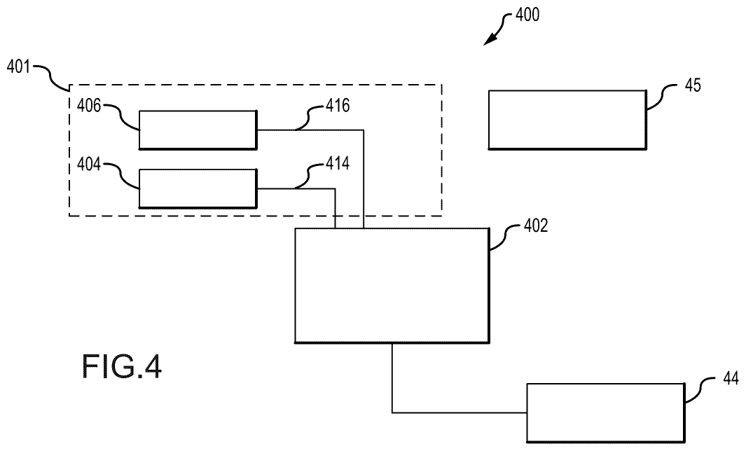

FIG. 4 illustrates a deposition assembly 400 according to the current disclosure in a schematic manner. Deposition assembly 400 can be used to perform a method as described herein and/or to selectively deposit organic material as described herein.

In the illustrated example, deposition assembly 400 includes one or more reaction chambers 402, a precursor injector system 401, a first precursor vessel 404, a second precursor vessel 406, an exhaust source 44, and a controller 45. The deposition assembly 400 may comprise one or more additional gas sources (not shown), such as an inert gas source, a carrier gas source and/or a purge gas source. Reaction chamber 402 can include any suitable reaction chamber, such as an ALD or CVD reaction chamber as described herein.

The first precursor vessel 404 can include a vessel and one or more first precursors as described herein—alone or mixed with one or more carrier (e.g., inert) gases. A second precursor vessel 406 can include a vessel and one or more second precursors as described herein—alone or mixed with one or more carrier gases. Although illustrated with two source vessels 404, 406, a deposition assembly 400 can include any suitable number of source vessels. Source vessels 404, 406 can be coupled to reaction chamber 402 via lines 414 and 416, which can each include flow controllers, valves, heaters, and the like. In some examples, the first precursor in the first precursor vessel 404 and the second precursor in the second precursor vessel 406 may be heated.

Exhaust source 44 can include one or more vacuum pumps. Controller 45 includes electronic circuitry and software to selectively operate valves, manifolds, heaters, pumps and other components included in the deposition assembly 400. Such circuitry and components operate to introduce precursors, reactants and purge gases from the respective sources. Controller 312 can control timing of gas pulse sequences, temperature of the substrate and/or reaction chamber 402, pressure within the reaction chamber 402, and various other operations to provide proper operation of the deposition assembly 400. Controller 45 can include control software to electrically or pneumatically control valves to control flow of precursors, reactants and purge gases into and out of the reaction chamber 402. Controller 45 can include modules such as a software or hardware component, which performs certain tasks. A module may be configured to reside on the addressable storage medium of the control system and be configured to execute one or more processes.

Other configurations of deposition assembly 400 are possible, including different numbers and kinds of precursor and reactant sources. Further, it will be appreciated that there are many arrangements of valves, conduits, precursor sources, and auxiliary reactant sources that may be used to accomplish the goal of selectively and in coordinated manner feeding gases into reaction chamber 402. Further, as a schematic representation of a deposition assembly, many components have been omitted for simplicity of illustration, and such components may include, for example, various valves, manifolds, purifiers, heaters, containers, vents, and/or bypasses.

During operation of deposition assembly 400, substrates, such as semiconductor wafers (not illustrated), are transferred from, e.g., a substrate handling system to reaction chamber 402. Once substrate(s) are transferred to reaction chamber 402, one or more gases from gas sources, such as precursors, reactants, carrier gases, and/or purge gases, are introduced into reaction chamber 402.

In a further aspect, a deposition assembly for selectively depositing a layer of organic material on a substrate is disclosed. The deposition assembly comprises one or more reaction chambers constructed and arranged to hold the substrate, and a precursor injector system constructed and arranged to provide a first precursor and a second precursor into the reaction chamber in a vapor phase. The deposition assembly also comprises a precursor vessel constructed and arranged to contain a first precursor, and the assembly is constructed and arranged to provide the first precursor and the second precursor via the precursor injector system to the reaction chamber to deposit a layer of organic material on the substrate. In an example, the first precursor may comprise a diamine bonded to a cyclic carbon backbone, or a carbon backbone including one or more carbon-carbon double bonds and/or carbon-carbon triple bonds. In another example, the first precursor may comprise a triamine compound comprising at least three carbon atoms wherein the amine groups are primary amines.

Although exemplary examples of the present disclosure are set forth herein, it should be appreciated that the disclosure is not so limited. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

What is claimed is:

1. A method for selectively depositing a layer of organic material on a substrate comprising a first surface and a second surface by a cyclic deposition process, the process comprising:
providing a substrate in a reaction chamber;
providing a first vapor-phase precursor in the reaction chamber; and
providing a second vapor-phase precursor in the reaction chamber,
wherein the first and second vapor-phase precursors form the organic material selectively on the first surface relative to the second surface; and wherein the first vapor-phase precursor comprises a triamine compound comprising three amine groups and at least three carbon atoms, wherein the amine groups are primary amines.

2. The method of claim 1, wherein the second vapor-phase precursor comprises a dianhydride.

3. The method of claim 1, wherein the organic material comprises a polyimide.

4. The method of claim 1, wherein the organic material comprises a polyamic acid.

5. The method of claim 1, wherein the second surface comprises an inorganic dielectric surface.

6. The method of claim 1, wherein the second surface comprises silicon.

7. The method of claim 6, wherein the second surface comprises SiO₂.

8. The method of claim 1, wherein the organic material is deposited on the first surface relative to the second surface with a selectivity of above about 50%.

9. The method of claim 1, wherein the first surface comprises a metal oxide, metal nitride, elemental metal, or metallic surface.

10. The method of claim 1, wherein the first surface comprises a metal selected from a group consisting of aluminum, copper, tungsten, cobalt, nickel, niobium, iron, molybdenum, indium, gallium, manganese, zinc, ruthenium and vanadium.

11. The method of claim 1, wherein the triamine compound is a C3 to C11 compound.

12. The method of claim 1, wherein the triamine is a triaminopropane, triamino butane, triamino pentane, triamino hexane, triamino heptane, or triamino octanes, or a combination thereof.

13. The method of claim 1, wherein the triamine compound is: tris(aminoethyl)phosphane;
tris(aminoethyl)arsane; bis(aminoethyl)aminomethylamine; tris(aminoethyl)silane;
tris(aminoethyl)stannane; tris(aminoethyl)methylsilane; 2-methylbenzene-1,3,5-triamine;
pentane-1,2,4-triamine; cyclohexane-1,3,5-triamine; pentane-1,3,5-triamine; tris(2-aminoethyl)amine; 2-aminomethyl-1,3-diaminopropane; 2-(aminomethyl)propane-1,3-diamine; propane-1,2,3-triamine; 2-aminomethyl-1,4-diaminobutane; tris(2-aminoethyl)phosphane; 2-aminomethyl-1,5-diaminopentane; 3-aminomethyl-1,5-diaminopentane; 2-aminomethyl-1,6-diaminohexane; 3-aminomethyl-1,6-diaminohexane;
3-aminoethyl-1,6-diaminohexane; 1,3,5-triaminobenzene, or combinations thereof.

14. The method of claim 13, wherein the triamine compound comprises a cis- or trans stereoisomer, or combination thereof.

15. The method of claim 1, wherein the method comprises a preclean comprising a reduction and an oxidation step before depositing the organic material on the first surface of the substrate.

16. A method for selectively depositing a layer of organic material on a substrate comprising a first surface and a second surface by a cyclic deposition process, the process comprising:
contacting the substrate with a first vapor-phase precursor; and
contacting the substrate with a second vapor-phase precursor, wherein
the first and second vapor-phase precursors form the organic material selectively on the first surface relative to the second surface, wherein the first vapor-phase precursor comprises a triamine compound comprising at least three carbon atoms wherein the amine groups are primary amines.

17. A method for selectively depositing a layer of organic material on a substrate comprising a first surface and a second surface by a cyclic deposition process, the process comprising:
providing a substrate in a reaction chamber;
providing a first vapor-phase precursor in the reaction chamber; and
providing a second vapor-phase precursor in the reaction chamber, wherein the first and second vapor-phase precursors form the organic material selectively on the first surface relative to the second surface; and wherein the first vapor-phase precursor comprises a diamine compound having both amine groups bonded to a cyclic carbon backbone, or a backbone with one or more carbon-carbon double bonds or carbon-carbon triple bonds, or a combination thereof.

18. The method of claim 17, wherein the diamine comprises trans-1,4-diaminocyclohexane, 2,4-diamino-2,4-dimethylpentane, 1,5-diamino-2-methylpentane, 1,3-diamino-3-methylbutane, 2,5-diamino-2,5-dimethylhexane, 1,2-diaminocyclopropane, 1,3-diaminocyclobutane, 1,3-diaminocyclohexane, 1,3-diaminocyclopentane, 1,4-diaminocyclohexane; 1,3-diaminocycloheptane, 1,4-diaminocycloheptane, 2,7-diamino-2,7-dimethyloctane, diaminocyclohexane, 1,3-diaminobenzene and 1,4-diaminobenzene, or cis or trans stereoisomers thereof.

19. A method of selectively depositing an inorganic material on a second surface of a substrate relative to a first surface of the substrate by a cyclic deposition process, wherein the process comprises depositing a layer of organic material on the first surface by
providing a substrate in a reaction chamber;
providing a first vapor-phase precursor in the reaction chamber;
providing a second vapor-phase precursor in the reaction chamber, wherein the first and second vapor-phase precursors form the organic material selectively on the first surface relative to the second surface, wherein the first vapor-phase precursor comprises a triamine compound comprising three primary amines and at least three carbon atoms; and
depositing the inorganic material on the second surface.

20. A deposition assembly for selectively depositing a layer of organic material on a substrate comprising:
one or more reaction chambers constructed and arranged to hold the substrate; and a precursor injector system constructed and arranged to provide a first precursor and a second precursor into the reaction chamber in a vapor phase, wherein the deposition assembly comprises a precursor vessel constructed and arranged to contain the first precursor, wherein the assembly is arranged to provide the first precursor comprising a triamine compound and the second precursor comprising a dianhydride via the precursor injector system to the reaction chamber to deposit a layer of organic material on the substrate, and wherein the triamine compound comprises at least three carbon atoms and wherein the amine groups are primary amines.
